(19) United States
(12) Patent Application Publication
(10) Pub. No.: US 2015/0216092 A1
(43) Pub. Date: Jul. 30, 2015

(54) FORCED CONVECTION PRE-HEATER FOR WAVE SOLDER MACHINE AND RELATED METHOD

(71) Applicant: Illinois Tool Works Inc., Glenview, IL (US)

(72) Inventor: Jonathan M. Dautenhahn, Linn Creek, MO (US)

(73) Assignee: Illinois Tool Works Inc., Glenview, IL (US)

(21) Appl. No.: 14/165,761

(22) Filed: Jan. 28, 2014

(51) Int. Cl. H05K 13/04; B23K 3/08; B23K 1/012; B23K 1/20; B23K 1/00; B23K 3/06; B23K 37/04

(52) U.S. Cl. CPC H05K 13/0465; B23K 3/0653; B23K 3/082; B23K 37/04; B23K 1/20; B23K 1/0016; B23K 1/012; B23K 2201/42

(57) ABSTRACT

A wave solder machine is configured to perform a wave solder operation on an electronic substrate. The wave solder machine includes a pre-heating station configured to heat the electronic substrate, a wave soldering station configured to attach electronic components to the electronic substrate with solder, and a conveyor configured to transport substrates through a tunnel passing through the fluxing station, the pre-heating station and the wave soldering station. The pre-heating station includes at least one pre-heater including an outer chamber housing, a compression box assembly disposed in the outer chamber housing, a diffuser plate disposed above the compression box assembly, and at least one heating element disposed in the outer chamber housing. The pre-heater is configured to draw heated gas into the compression box assembly from the tunnel, heat the gas, and exhaust the heated gas out to the tunnel through the diffuser plate.

### BACKGROUND OF THE INVENTION

1. Field of the Disclosure

This application relates generally to the surface mount of electronic components onto a printed circuit board by employing a wave soldering process, and more particularly to a pre-heating station that is designed to provide uniform flow of heated gas to the printed circuit board prior to performing the wave soldering process.

2. Discussion of Related Art

In the fabrication of printed circuit boards, electronic components can be mounted to a printed circuit board by a process known as “wave soldering.” In a typical wave solder machine, a printed circuit board is moved by a conveyor on an inclined path past a fluxing station, a pre-heating station, and finally a wave soldering station. At the wave soldering station, a wave of solder is caused to well upwardly (by means of a pump) through a wave solder nozzle and contact portions of the printed circuit board to be soldered. As used herein, the term “circuit board” or “printed circuit board,” as used herein, includes any type of substrate assembly of electronic components, including, for example, wafer substrates.

The wave soldering process has recently advanced by transitioning from traditional tin-lead solder to lead-free materials. These new soldering materials have reduced the process windows and require that the temperature variances across a printed circuit board be reduced. The importance of reduced temperature variance, known in the industry as ΔT, has driven the optimization of the design of the pre-heater for uniform airflow. There is presently a need for a pre-heater that produces a forced convection that provides uniform airflow, and thus reduces the temperature variance across the printed circuit board within the wave solder machine.

### BRIEF SUMMARY OF THE INVENTION

One aspect of the disclosure is directed to a wave solder machine configured to perform a wave solder operation on an electronic substrate. In one embodiment, the wave solder machine comprises a pre-heating station configured to heat the electronic substrate, a wave soldering station configured to attach electronic components to the electronic substrate with solder, and a conveyor configured to transport substrates through a tunnel passing through the fluxing station, the pre-heating station and the wave soldering station. The pre-heating station includes at least one pre-heater including an outer chamber housing, a compression box assembly disposed in the outer chamber housing, a diffuser plate disposed above the compression box assembly, and at least one heating element disposed in the outer chamber housing. The pre-heater is configured to draw heated gas into the compression box assembly from the tunnel, heat the gas, and exhaust the heated gas out to the tunnel through the diffuser plate.

Embodiments of the wave solder machine further may include at least two heating elements disposed at opposite ends of the compression box assembly within the outer chamber housing. The compression box assembly may include a compression box housing having at least one intake port located adjacent the at least one heating element, and an intake duct disposed in the compression box housing. The intake duct has at least one inlet opening in fluid communication with the at least one intake port of the compression box housing and an outlet opening. The compression box assembly further may include a pressure distribution device positioned between the intake duct and the compression box housing at a location of the outlet opening. The pressure distribution device may include at least one vane to enable fluid communication from outlet opening of the intake duct to the diffuser plate. The compression box assembly further may include a blower device positioned within the pressure distribution device. The blower device may be configured to direct heated gas from the intake duct to the diffuser plate. The compression box assembly further may include a pressure equalizing plate positioned between the intake duct and the diffuser plate. The pressure equalizing plate may extend from one end of the intake duct to an opposite end of the intake duct. The diffuser plate may include a plurality of openings formed therein. The each opening may have a protruding nozzle formed around the opening. The compression box housing may include two intake ports, and the intake duct may include two inlet openings aligned to and in fluid communication with the two intake ports of the compression box housing. The compression box housing may have two ends, each end having an intake port, and the intake duct may include two open ends, each side having an inlet opening.

Another aspect of the present disclosure is directed to a method of distributing heated gas within a wave soldering machine of the type comprising a pre-heating station configured to heat the electronic substrate, a wave soldering station configured to attach electronic components to the electronic substrate with solder, and a conveyor configured to transport substrates through a tunnel passing through the fluxing station, the pre-heating station and the wave soldering station, the pre-heating station including at least one pre-heater including an outer chamber housing, a compression box assembly disposed in the outer chamber housing, a diffuser plate disposed above the compression box assembly, and at least one heating element disposed in the outer chamber housing. In one embodiment, the method comprises: drawing gas into the outer chamber housing between the outer chamber housing and the compression box assembly from the tunnel; heating the gas; and exhausting the heated gas out to the tunnel through the diffuser plate.

Embodiments of the method further may include positioning a pressure distribution device within the compression box assembly. The method further may include positioning a blower device in the pressure distribution device, the blower device being configured to direct heated gas from the compression box assembly to the diffuser plate. The method further may include positioning a pressure equalizing plate within the compression box assembly.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a perspective view of a wave solder machine;

FIG. 2 is a side elevational view of the wave solder machine with external packaging removed to reveal internal components of the wave solder machine, including multiple pre-heater assemblies;

FIG. 3 is an exploded perspective view of a pre-heater assembly of an embodiment of the present disclosure;

FIG. 4 is an exploded perspective view of a compression box assembly of the pre-heater assembly;

FIG. 5 is an enlarged perspective view of a diffuser plate of the pre-heater assembly;

FIG. 6 is a side cross-sectional view of the pre-heater assembly showing gas flow within the pre-heater assembly; and

FIG. 7 is a front cross-sectional view of the pre-heater assembly showing gas flow within the pre-heater assembly.

### DETAILED DESCRIPTION OF THE INVENTION

For the purposes of illustration only, and not to limit the generality, the present disclosure will now be described in detail with reference to the accompanying figures. This disclosure is not limited in its application to the details of construction and the arrangement of components set forth in the following description or illustrated in the drawings. The principles set forth in this disclosure are capable of other embodiments and of being practiced or carried out in various ways. Also the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

Wave solder machines are typically designed to incorporate a series of pre-heaters which serve the purpose of heating a printed circuit board (“PCB”) prior to contact with the molten solder bath. The wave solder machine of embodiments of the present disclosure is configured to optimize the airflow within and exiting the pre-heater to provide uniform forced convection heating of a printed circuit board across its entire width.

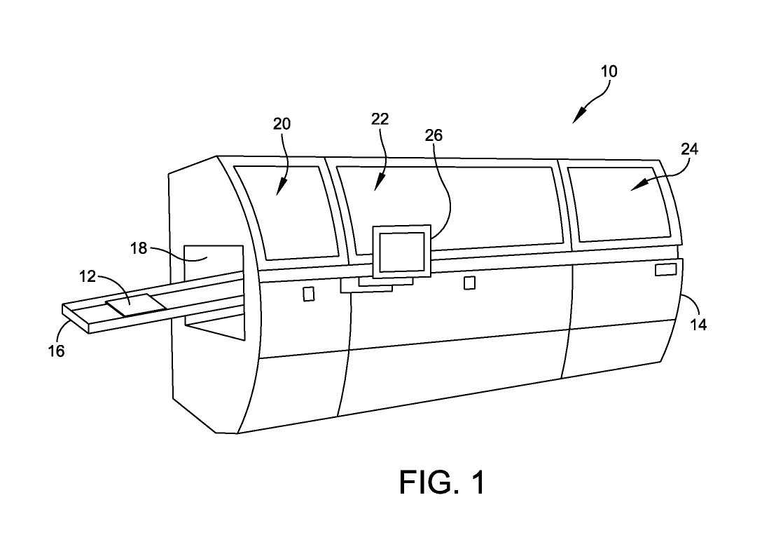

For purposes of illustration, and with reference to FIG. 1, embodiments of the present disclosure will now be described with reference to a wave solder machine, generally indicated at 10, which is used to perform a solder application on a printed circuit board 12, which may be referred to herein as an electronic substrate. The wave solder machine 10 is one of several machines in a printed circuit board fabrication/assembly line. As shown, the wave solder machine 10 includes a housing 14 adapted to house the components of the machine. The arrangement is such that a conveyor 16 delivers printed circuit boards to be processed by the wave solder machine 10. Upon entering the wave solder machine 10, each printed circuit board 12 travels along an inclined path along the conveyor 16 through a tunnel 18, which includes a fluxing station, generally indicated at 20, and a pre-heating station, generally indicated at 22, to condition the printed circuit board for wave soldering. Once conditioned (i.e., heated), the printed circuit board 12 travels to a wave soldering station, generally indicated at 24, to apply solder material to the printed circuit board. A controller 26 is provided to automate the operation of the several stations of the wave solder machine 10, including but not limited to the fluxing station 20, the pre-heating station 22, and the wave soldering station 24, in the well known manner.

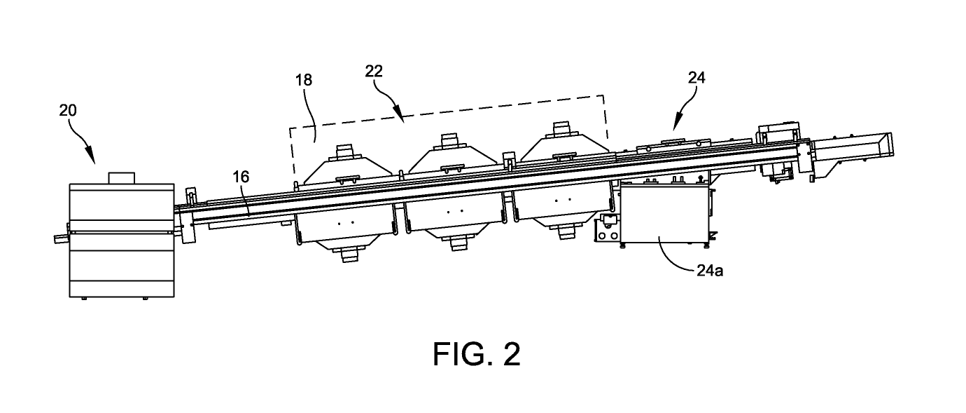

Referring to FIG. 2, the fluxing station 20 is configured to apply flux to the printed circuit board as it travels on the conveyor 16 through the wave solder machine 10. The pre-heating station 22 includes several pre-heaters, which are designed to incrementally increase the temperature of the printed circuit board as it travels along the conveyor 16 through the tunnel 18 to prepare the printed circuit board for the wave soldering process. As shown, the wave soldering station 24 includes a wave solder nozzle in fluid communication with a reservoir 24a of solder material. A pump is provided within the reservoir to deliver molten solder material to the wave solder nozzle from the reservoir. Once soldered, the printed circuit board exits the wave solder machine 10 via the conveyor 16 to another station provided in the fabrication line, e.g., a pick-and-place machine. In some embodiments, the wave solder machine 10 may be further configured to include a flux management system to remove volatile contaminants from the tunnel 18 of the wave solder machine.

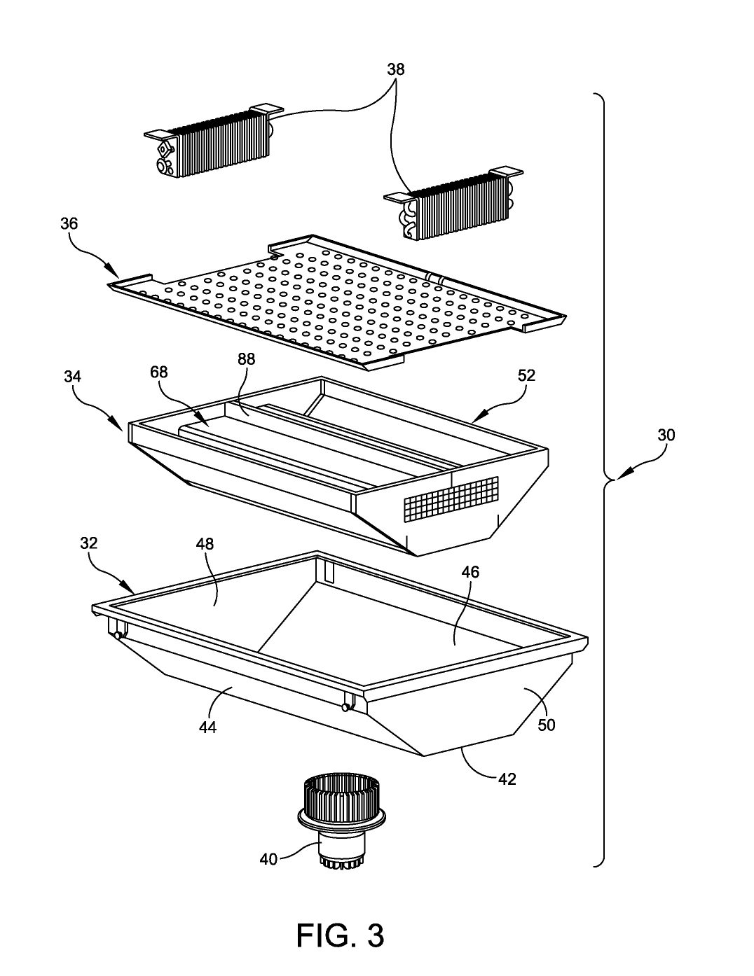

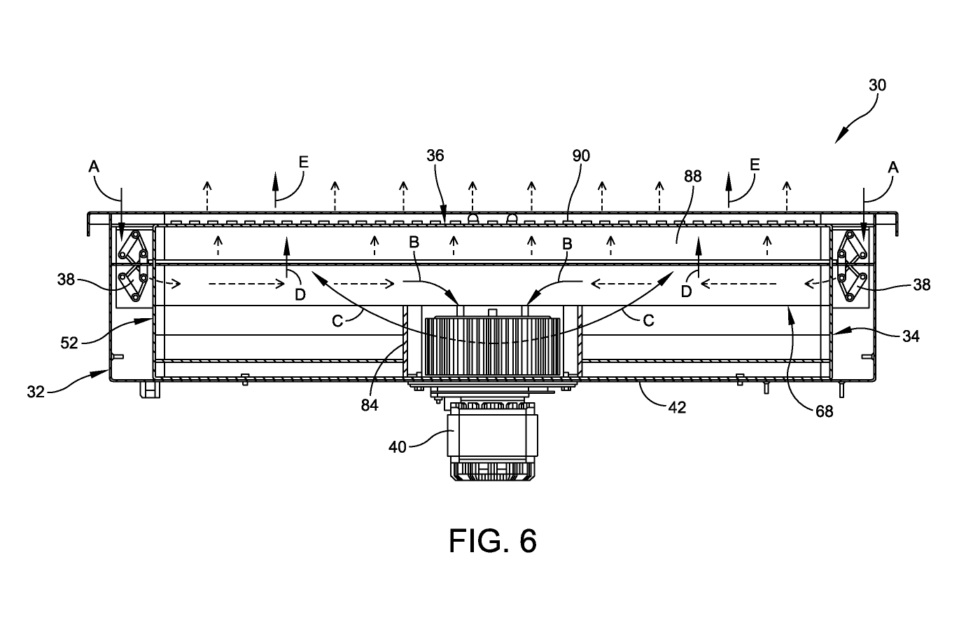

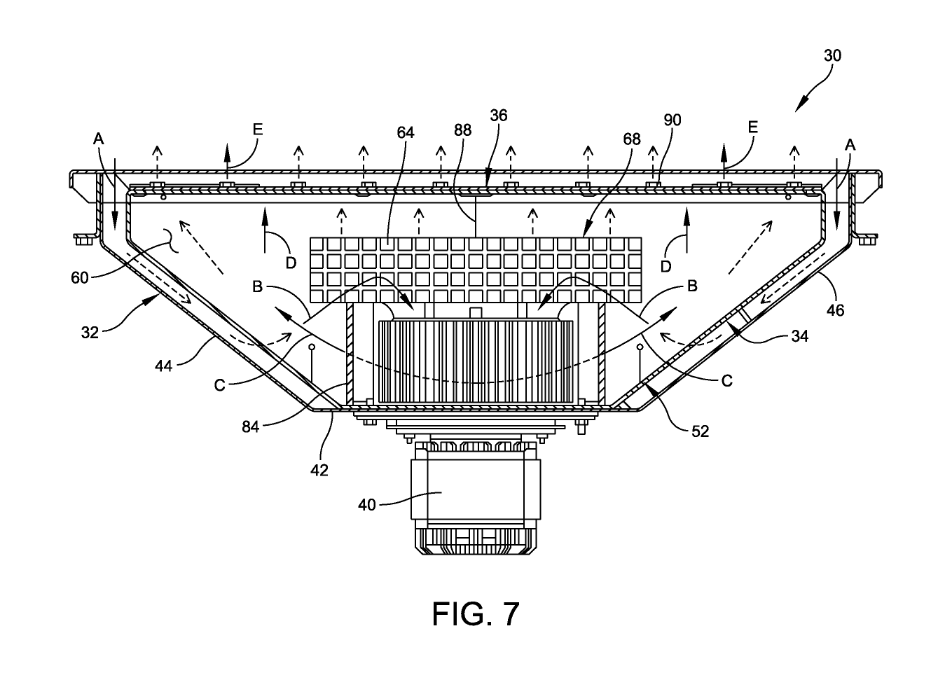

Referring to FIG. 3, which illustrates one of the pre-heaters of the pre-heating station 22, the pre-heater, generally indicated at 30, includes the following component parts. In one embodiment, the pre-heater 30 includes an outer chamber housing generally indicated at 32 to enclose and mount components of the pre-heater, a compression box assembly generally indicated at 34 to equalize gas pressure for uniform airflow, a diffuser plate 36 to distribute heated gas to printed circuit boards traveling above the pre-heater, two heaters, each indicated at 38, to provide convection heating to the gas that flows into the compression box assembly, and a blower 40 to provide gas movement within the pre-heater. As configured, the compression box assembly 34 and the diffuser plate 36 enable the pre-heater 30 to provide and otherwise supply uniform airflow to a printed circuit board traveling above the pre-heater on the conveyor 16 through the tunnel 18. The movement of gas within the pre-heater 30 to heat and evenly distribute the gas will be described in greater detail below with reference to FIGS. 6 and 7.

The outer chamber housing 32 is configured to be supported by the housing 14 of the wave solder machine 10. As shown in FIG. 3, the outer chamber housing 32 includes a bottom wall 42, two slanted side walls 44, 46, and two end walls 48, 50. The outer chamber housing 32 is configured and shaped to receive the compression box assembly 34 therein with the compression box assembly being seated on the bottom wall 42 of the outer chamber housing. The bottom wall 42 has an opening formed therein to secure the blower 40 to the outer chamber housing 32 so that the blower extends into an interior of the outer chamber housing.

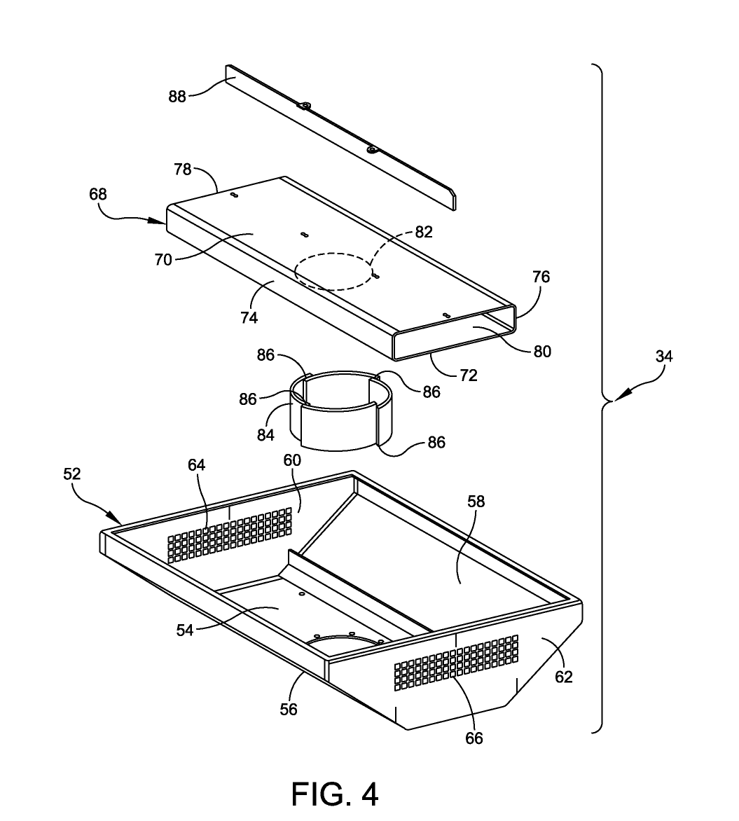

Referring to FIG. 4, the compression box assembly 34 is configured to distribute uniform airflow of heated gas to pre-heat printed circuit boards prior to being subjected to the wave soldering process. In one embodiment, the compression box assembly 34 includes a compression box housing, generally indicated at 52, having a bottom wall 54, two slanted side walls 56, 58, which correspond to the slanted walls 44, 46 of the outer chamber housing 32, and two end walls 60, 62, which correspond to the end walls 48, 50 of the outer chamber housing. As shown in FIG. 3, the compression box housing 52 is designed to fit within and be secured the outer chamber housing 32 so that there is a space between the compression box housing and the outer chamber housing. This space can be seen in FIGS. 6 and 7. Suitable spacing elements may be provided to achieve the desired spacing. Each end wall 60, 62 has a respective intake port 64, 66 formed therein by creating a series of small openings in a rectangular pattern. In one embodiment, each intake port 64, 66 is fabricated by stamping the sheet metal of the compression box housing 52 with 3/8-inch perforated square openings. This pattern of openings provides an optimum combination of intake versus discharge pressures for stable blower operation during operation of the blower 40.

The compression box assembly 34 further includes a two-way intake duct generally indicated at 68. The intake duct 68 includes a rectangular body having a top 70, a bottom 72, two long sides 74, 76, and two open ends 78, 80. The open ends 78, 80 of the intake duct 68 are each shaped to correspond to the shape and size of its respective intake port 64, 66 provided at the end 60, 62 of the compression box housing 52. The open ends 78, 80 enable gas to be drawn into the intake duct 68 from completely around a perimeter of the compression box housing 52. The construction of the compression box assembly 34 is designed to force the majority of the gas to be drawn on the end walls 60, 62 of the compression box housing 52 through the heaters 38. The bottom 72 of the intake duct 68 includes an outlet 82 (shown in dashed lines in FIG. 4) to direct gas to the blower 40.

In one embodiment, the compression box assembly 34 further includes a pressure distribution device 84 that is positioned between the intake duct 68 and the bottom wall 54 of the compression box housing 52. As shown, the pressure distribution device 84 includes four vanes each indicated at 86 that are designed to “peel-off” and equally distribute the gas pressure from the blower 40 to all parts of the compression box assembly 34. As shown, the blower 40 is secured to an outer surface of the bottom wall 54 (e.g., by suitable fasteners) of the compression box housing 52. The arrangement is such that the blower 40 is positioned within the pressure distribution device 84 to drive the movement of gas from the intake duct 68 through the outlet opening 82 and around the outer surfaces of the intake duct to the diffuser plate 36.

In one embodiment, the compression box assembly further includes a pressure equalizing plate 88 that is positioned between the intake duct 68 and the diffuser plate 36. As shown, the pressure equalizing plate 88 extends from one end (e.g., end 78) of the intake duct 68 to an opposite end (e.g., end 80) of the intake duct. The pressure equalizing plate 88 bisects the compression box housing 52 from end-to-end and extends from the bottom of the diffuser plate 36 to the top of the intake duct 68. The provision of the pressure equalizing plate 88 is designed to segregate the compression box assembly 34, which results in equal pressure distribution under the diffuser plate 36.

Referring back to FIG. 3, there are two heaters or heating elements 38 provided for the compression box assembly 34. The arrangement is such that the heaters 38 are positioned at the ends of the compression box assembly 34. The placement and number of the heaters 38 within the pre-heater 30 may be varied to maximize the heating of the gas circulating through the compression box assembly.

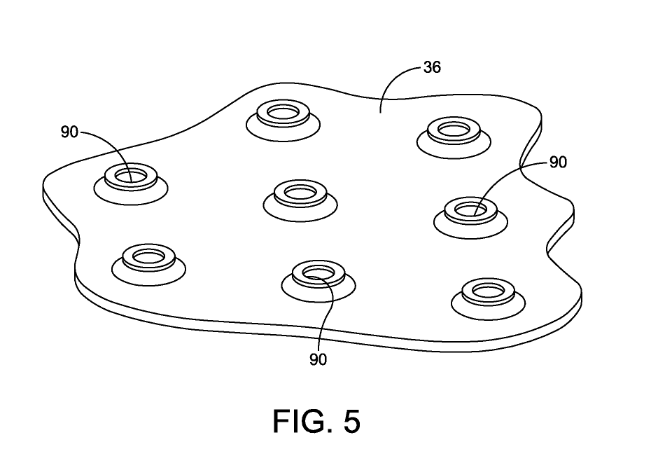

Referring to FIG. 5, the diffuser plate 36 is configured to distribute gas from the compression box assembly 34 to the tunnel 18 of the wave solder machine 10. In a certain embodiment, the diffuser plate consists of 175 holes, each indicated at 90, in a staggered pattern to provide consistent, uniform airflow to the printed circuit board. These holes 90 are stamped from sheet metal material such that they form a converging nozzle that results in a uniform airstream. Another aspect of the use of the protruding convergent nozzle is the ability to inhibit accidental solder spills from penetrating the pre-heater 30 through the diffuser holes 90.

FIGS. 6 and 7 illustrate the airflow through the compression box assembly 34 as generated by the blower device 40 with gas entering the intake duct 68 and exiting the diffuser plate 36. Specifically, gas enters the intake duct as illustrated by arrows A. The gas entering the intake duct 68 transitions into the blower device 40 via outlet opening (not designated) as illustrated by arrows B. The blower device 40 moves gas through the pressure distribution device 84 where gas exits the vanes (not designated) as illustrated by arrows C. The gas travels into the space between the top of the intake duct 68 and the diffuser plate 36 as defined by the pressure equalizing plate 88 as illustrated by arrows D. Gas then exits the compression box assembly 34 into the tunnel through the diffuser plate 36 as illustrated by arrows E.

Embodiments of the pre-heater may be varied to achieve a more uniform airflow across the printed circuit board during the pre-heating of the printed circuit board. For example, the number of holes, hole pattern, hole size, and hole shape in the diffuser plate may be varied. In another embodiment, the placement of the heaters in relation to the compression box may be varied. The number of holes, hole pattern, hole size and hole shape of the compression box housing intake ports may be varied as well. And finally, the number, size, and orientation of the outlet pressure distribution vanes may be varied.

Thus, it should be observed that the pre-heater of embodiments of the present disclosure optimize airflow through the pre-heater to supply uniform airflow to the printed circuit board. The pre-heater further eliminates large temperature variances across a printed circuit board, which can result in insufficient heating or overheating of the printed circuit board and/or its components. These defects can result in rework and/or scrap of the printed circuit board, which can be extremely costly to a printed circuit board manufacturer.

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the disclosure. Accordingly, the foregoing description and drawings are by way of example only.

What is claimed is:

1. A wave solder machine configured to perform a wave solder operation on an electronic substrate, the wave solder machine comprising:
a pre-heating station configured to heat the electronic substrate;
a wave soldering station configured to attach electronic components to the electronic substrate with solder; and
a conveyor configured to transport substrates through a tunnel passing through the fluxing station, the pre-heating station and the wave soldering station,
wherein the pre-heating station includes at least one pre-heater including
an outer chamber housing,
a compression box assembly disposed in the outer chamber housing,
a diffuser plate disposed above the compression box assembly, and
at least one heating element disposed in the outer chamber housing,
the pre-heater being configured to draw heated gas into the compression box assembly from the tunnel, heat the gas, and exhaust the heated gas out to the tunnel through the diffuser plate.

2. The wave solder machine of claim 1, wherein the compression box assembly includes
a compression box housing having at least one intake port located adjacent the at least one heating element, and
an intake duct disposed in the compression box housing, the intake duct having at least one inlet opening in fluid communication with the at least one intake port of the compression box housing and an outlet opening.

3. The wave solder machine of claim 2, wherein the compression box assembly further includes a pressure distribution device positioned between the intake duct and the compression box housing at a location of the outlet opening.

4. The wave solder machine of claim 3, wherein the pressure distribution device includes at least one vane to enable fluid communication from outlet opening of the intake duct to the diffuser plate.

5. The wave solder machine of claim 3, wherein the compression box assembly further includes a blower device positioned within the pressure distribution device, the blower device being configured to direct heated gas from the intake duct to the diffuser plate.

6. The wave solder machine of claim 2, wherein the compression box assembly further includes a pressure equalizing plate positioned between the intake duct and the diffuser plate.

7. The wave solder machine of claim 6, wherein the pressure equalizing plate extends from one end of the intake duct to an opposite end of the intake duct.

8. The wave solder machine of claim 2, wherein the diffuser plate includes a plurality of openings formed therein.

9. The wave solder machine of claim 8, wherein each opening has a protruding nozzle formed around the opening.

10. The wave solder machine of claim 2, wherein the compression box housing includes two intake ports, and wherein the intake duct includes two inlet openings aligned to and in fluid communication with the two intake ports of the compression box housing.

11. The wave solder machine of claim 10, wherein the compression box housing has two ends, each end having an intake port, and wherein the intake duct includes two open ends, each side having an inlet opening.

12. The wave solder machine of claim 1, further comprising at least two heating elements disposed at opposite ends of the compression box assembly within the outer chamber housing.

13. A method of distributing heated gas within a wave soldering machine of the type comprising a pre-heating station configured to heat the electronic substrate, a wave soldering station configured to attach electronic components to the electronic substrate with solder, and a conveyor configured to transport substrates through a tunnel passing through the fluxing station, the pre-heating station and the wave soldering station, the pre-heating station including at least one pre-heater including an outer chamber housing, a compression box assembly disposed in the outer chamber housing, a diffuser plate disposed above the compression box assembly, and at least one heating element disposed in the outer chamber housing, the method comprising:
drawing gas into the outer chamber housing between the outer chamber housing and the compression box assembly from the tunnel;
heating the gas; and
exhausting the heated gas out to the tunnel through the diffuser plate.

14. The method of claim 13, further comprising positioning a pressure distribution device within the compression box assembly.

15. The method of claim 14, further comprising positioning a blower device in the pressure distribution device, the blower device being configured to direct heated gas from the compression box assembly to the diffuser plate.

16. The method of claim 13, further comprising positioning a pressure equalizing plate within the compression box assembly.
